(19) United States
(12) Patent Application Publication
(10) Pub. No.: US 2014/0014180 A1
(43) Pub. Date: Jan. 16, 2014

(54) ENCAPSULANT FOR A PHOTOVOLTAIC MODULE

(71) Applicants: Stéphane Bizet, Barc (FR); Samuel Devisme, Rouen (FR); Thomas Fine, Lyon (FR); Dominique Jousset, Bougival (FR)

(72) Inventors: Stéphane Bizet, Barc (FR); Samuel Devisme, Rouen (FR); Thomas Fine, Lyon (FR); Dominique Jousset, Bougival (FR)

(73) Assignee: ARKEMA FRANCE, COLOMBES (FR)

(21) Appl. No.: 13/996,588

(22) PCT Filed: Nov. 17, 2011
(86) PCT No.: PCT/FR11/52674

§ 371 Date: Sep. 30, 2013

(30) Foreign Application Priority Data
Dec. 23, 2010 (FR) 1061150

(51) Int. Cl. H01L 31/048

(52) U.S. Cl. CPC H01L 31/0481
USPC 136/259; 428/476.9; 428/215; 428/76

(57) ABSTRACT

An encapsulant for a photovoltaic module, intended to coat a photovoltaic cell, including at least two adjacent thermoplastic layers forming a core-skin assembly, wherein the skin layer consists of a polyamide-grafted polymer including a polyolefin backbone, representing from 50% to 95% by weight of the polyamide-grafted polymer, containing a residue of at least one unsaturated monomer (X) and at least one polyamide graft, representing from 5% to 50% by weight of polyamide-grafted polymer, the core layer including a polyethylene chosen from a homopolymer of ethylene or a copolymer including at least 50 mol % of ethylene and one or more comonomers. Also, a photovoltaic module incorporating such an encapsulant.

### FIELD OF THE INVENTION

One subject of the invention is an encapsulant for a photovoltaic module having a particular core-skin structure that gives it optimum properties for this application. The present invention also relates to a photovoltaic module comprising, besides the encapsulant layer, at least one adjacent layer forming a “frontsheet” or “backsheet”, more generally these three successive layers, “frontsheet”, encapsulant and “backsheet”.

Global warming, linked to the greenhouse gases released by fossil fuels, has led to the development of alternative energy solutions which do not emit such gases during their operation, such as for example photovoltaic modules. A photovoltaic module comprises a “photovoltaic cell”, this cell being capable of converting light energy into electricity.

There are many types of photovoltaic panel structures.

In FIG. 1, a conventional photovoltaic cell has been represented; this photovoltaic cell 10 comprises cells 12, one cell containing a photovoltaic sensor 14, generally based on silicon that is treated in order to obtain photoelectric properties, in contact with electron collectors 16 placed above (upper collectors) and below (lower collectors) the photovoltaic sensor. The upper collectors 16 of one cell are connected to the lower collectors 16 of another cell 12 by conducting bars 18, generally consisting of an alloy of metals. All these cells 12 are connected to one another, in series and/or in parallel, in order to form the photovoltaic cell 10. When the photovoltaic cell 10 is placed under a light source, it delivers a continuous electric current, which may be recovered at the terminals 19 of the cell 10.

With reference to FIG. 2, the photovoltaic module 20 comprises the photovoltaic cell 10 from FIG. 1 encased in an “encapsulant”, the latter being composed of an upper portion 22 and a lower portion 23. An upper protective layer 24 (known under the term “frontsheet”, used hereinafter) and a protective layer on the back of the module (known under the term “backsheet”, also used hereinafter) 26 are positioned on either side of the encapsulated cell.

The impact and moisture protection of the photovoltaic cell 10 is provided by the upper protective layer 24, generally made of glass.

The backsheet 26, for example a multilayer film based on a fluoropolymer and polyethylene terephthalate, contributes to the moisture protection of the photovoltaic module 20 and to the electrical insulation of the cells 12 to prevent any contact with the outside environment.

The encapsulant 22 and 23 must perfectly adopt the shape of the space existing between the photovoltaic cell 10 and the protective layers 24 and 26 in order to avoid the presence of air, which would limit the efficiency of the photovoltaic module. The encapsulant 22 and 23 must also prevent contact of the cells 12 with water and oxygen from the air, in order to limit the corrosion thereof. The upper portion 22 of the encapsulant is between the cell 10 and the upper protective layer 24. The lower portion 23 of the encapsulant is between the cell 10 and the backsheet 26. In one embodiment variant of the encapsulant, there is no lower portion or upper portion so that the cells 12 of the cell are in contact respectively with the backsheet 26 or the frontsheet 24. This variant is illustrated in a figure where the photovoltaic cell 12 is seen in direct contact with the frontsheet 24 and is described in greater detail in particular in application WO 99/04971.

In the presence of solar radiation, a temperature rise is created inside the solar module and temperatures of 80° C. (or more) may be achieved. The thermomechanical properties, and in particular the creep resistance, of the adhesive, of the binder or of the encapsulant must therefore be maintained at these temperatures so that the solar module is not deformed. The creep resistance is more particularly important in the case of the encapsulant: indeed, in the event of creep, the cell may come back into contact with air and/or the upper and/or lower protective layers, which leads to a reduction in the efficiency of the solar module, or even a degradation of the cell and of the solar module. Moreover, the encapsulant may have good flame retardant properties (at least V2 classification in tests in accordance with UL94 classification).

Furthermore, so as not to reduce the efficiency of the solar module, it is necessary for the encapsulant to enable the transmission of the light waves of the solar radiation to the cells (satisfactory refractive index) and have good UV resistance. Again so as not to reduce the efficiency, it is desirable for these light waves to be barely diffracted, that is to say that the encapsulant must be, to the naked eye, transparent or slightly translucent, the transparency being quantified by its “haze”, which must be low, and its transmittance, which must be as high as possible. Of course, these considerations relating to the transparency of the encapsulant must be met for the portion of the latter located above the photovoltaic cells, so that, for the lower portion, it is not necessarily essential for the encapsulant to have such properties.

It is also necessary for the encapsulant to have good electrical insulation properties, in order to avoid any short-circuit within the module.

Thus, in the encapsulant or encapsulant-backsheet applications for photovoltaic modules, the materials or compositions must imperatively have a perfect transparency in order to allow the lossless transmission (or transmission with minimal loss) of the light radiation. Furthermore, this thermoplastic composition/material must have a good mechanical strength, in particular with respect to the elongation at break and tensile strength properties, and also good thermomechanical properties, in particular with respect to the hot creep test, considering the temperature rise of the photovoltaic module during prolonged exposure to the sun. Finally, this thermoplastic composition/material must also have a good level of fire resistance (flame retardancy).

An essential feature for an encapsulant is also its ability to adhere to various supports (in particular glasses, and various thermoplastic compositions and polymers), irrespective of the environmental conditions, in particular with regard to temperature conditions and in a moist atmosphere.

Furthermore, the encapsulant must have the best possible impermeability to water and to oxygen in order to avoid any risk of corrosion/oxidation of the conductive electric cells, often made of corrodible metal.

Finally, the encapsulant must be easily implemented during the step of lamination of the photovoltaic module/panel. The first role of an encapsulant aims to encase the electric cell and it is therefore necessary for the encapsulant to have excellent electrical insulation properties.

Finally, in certain cases, this thermoplastic composition/material may also have a good level of fire resistance (flame retardancy).

With regard to all of the properties that a photovoltaic module encapsulant must bring together, it is understood that it is particularly difficult to have such a structure exhibiting all these properties, given that a person skilled in the art knows that the improvement of some of these properties is obtained at the expense of others, for example obtaining good water impermeability properties takes place at the expense of the transparency and of the flexibility of the encapsulant.

Currently, there is no photovoltaic module encapsulant on the market that has an encapsulant consisting of a thermoplastic composition of core-skin type having satisfactory properties with regard to all of the aforementioned properties, namely particular optical properties (transparency, low haze and low refractive index), perfect adhesion to various supports, good creep resistance for a temperature above 80° C. and also good flame retardant properties, low water permeability, superior mechanical and impact strength properties, protection of the electric cells against corrosion, good UV (ultraviolet) resistance, ease of processing during the step of laminating the photo-voltaic module and perfect electrical insulation characteristics.

### PRIOR ART

Polyolefin-based encapsulants are currently known from documents WO 2008/036708, WO 2010/009017, US 2009/173384, WO 2008/036707 and EP 0 998 389.

Ethylene-based copolymers are described in documents WO 2008/036708 and WO 2008/036707 as materials that are incorporated into the composition of single-layer or multi-layer encapsulant films. Nevertheless, one of the main limits of encapsulants of this type lies in their low thermomechanical resistance due to their lack of cross-linking, combined with more difficult processing during lamination.

Similarly, the use of ionomers is described in document WO 95/22843 for producing encapsulant films for photovoltaic modules in order to solve the problems of thermomechanical properties, in particular the creep resistance.

These ionomers also have, to the naked eye, a good transparency but, although the thermomechanical properties are better than those of uncrosslinked ethylene/vinyl acetate (EVA), the creep resistance is not sufficient for this application in photovoltaic modules. Indeed, the formation of an ionic network enables the ionomer to retain a certain cohesion beyond its melting temperature but without its creep resistance being completely satisfactory. Another major problem of the ionomer is its high viscosity at the customary manufacturing temperatures of photovoltaic modules, generally within the range extending from 120° C. to 160° C., which makes the lamination step difficult.

Document EP 0 998 389 describes a multilayer encapsulant material comprising at least two layers of an ethylene/methacrylic acid copolymer or of ionomer with an intermediate layer of metallocene polyethylene. These encapsulant films may have a higher creep resistance than the ionomers for example, but these formulations have insufficient optical properties for being used as an encapsulant.

Finally, known from document WO 09/138679 is a thermoplastic composition constituting the encapsulant that has advantageous properties linked to the nanostructurations thereof, namely a transparency, a good creep resistance, a good adhesion and an ease of processing. Nevertheless, one of the major drawbacks lies in its low water impermeability. It will be noted that this document discloses an example of PE/encapsulant structure that is produced in order to allow peel tests so as to measure the adhesion of the encapsulant layer. Thus, the bilayer disclosed in this document, having two layers that can be completely separated from one another, is only a test material, that is to say a short-lived structure, and in no case a “photovoltaic module encapsulant” such as that of the present patent application.

### BRIEF DESCRIPTION OF THE INVENTION

It has been observed by the applicant, after various experiments and manipulations, that a particular structure could alone exhibit optimum results with regard to all of the characteristics desired for a photovoltaic module encapsulant.

Thus, the present invention relates to a photovoltaic module encapsulant, intended to encase a photovoltaic cell, comprising at least two adjacent thermoplastic layers forming a core-skin assembly, characterized in that:
the skin layer consists of a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
   the polyamide graft is attached to the polyolefin backbone by the residue of the unsaturated monomer (X) comprising a function capable of reacting via a condensation reaction with a polyamide having at least one amine end and/or at least one carboxylic acid end,
   the residue of the unsaturated monomer (X) is attached to the backbone by grafting or copolymerization,
   the polyolefin backbone and the polyamide graft being chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone;
the core layer consists of at least one polyolefin containing a polyethylene chosen from a homopolymer of ethylene or a copolymer chosen from an ethylene/α-olefin copolymer, the density of which is between 0.865 and 0.900 (ASTM D 1505 standard), and an ethylene/alkyl(meth)acrylate/anhydride copolymer.

Advantageously, the skin layer is nanostructured.

Preferably, the number-average molar mass of polyamide graft(s) is within the range extending from 1000 to 5000 g/mol (grams per mole), more preferably within the range extending from 2000 to 3000 g.mol⁻¹.

Other advantageous characteristics are defined below:
the at least one polyamide graft comprises at least one copolyamide.
the polyolefin backbone does not have a melting temperature or has a melting temperature below 110° C.
the number of monomers (X) attached to the polyolefin backbone is greater than or equal to 1.3 and/or less than or equal to 10.
the thickness of the encapsulant is between 10 μm and 2000 μm, the thickness of a skin layer varying from 1 μm to 1980 μm and the core layer having a thickness at least equal to 5 μm. Preferably, the thickness of said encapsulant is between 200 μm and 600 μm.
the encapsulant consists of two adjacent layers that form a core-skin assembly or of three adjacent layers forming a skin-core-skin assembly where the two skin layers surround the core layer and are preferably identical.
according to two embodiment variants, the core layer consists of a blend of polyolefins or of several different polyolefin layers positioned adjacent to one another.
according to one possibility offered by the invention, the homopolymer of ethylene is a linear low-density polyethylene (LLDPE), advantageously an LLDPE obtained by metallocene catalysis.

Finally, the invention also relates to a photovoltaic module comprising a structure consisting of a combination of at least one encapsulant and a frontsheet or backsheet, characterized in that the encapsulant is as described above.

### DESCRIPTION OF THE APPENDED FIGURES

The description which follows is given solely by way of illustration and nonlimitingly with reference to the appended figures, in which:

FIG. 1, already described, represents an example of a photovoltaic cell, the parts (a) and (b) being ¾ views, part (a) showing a cell before connection and part (b) a view after connection of two cells; part (c) is a top view of a complete photovoltaic cell.

FIG. 2, already described, represents a cross section of a photovoltaic module, the “conventional” photovoltaic sensor of which is encapsulated by an upper encapsulant film and a lower encapsulant film.

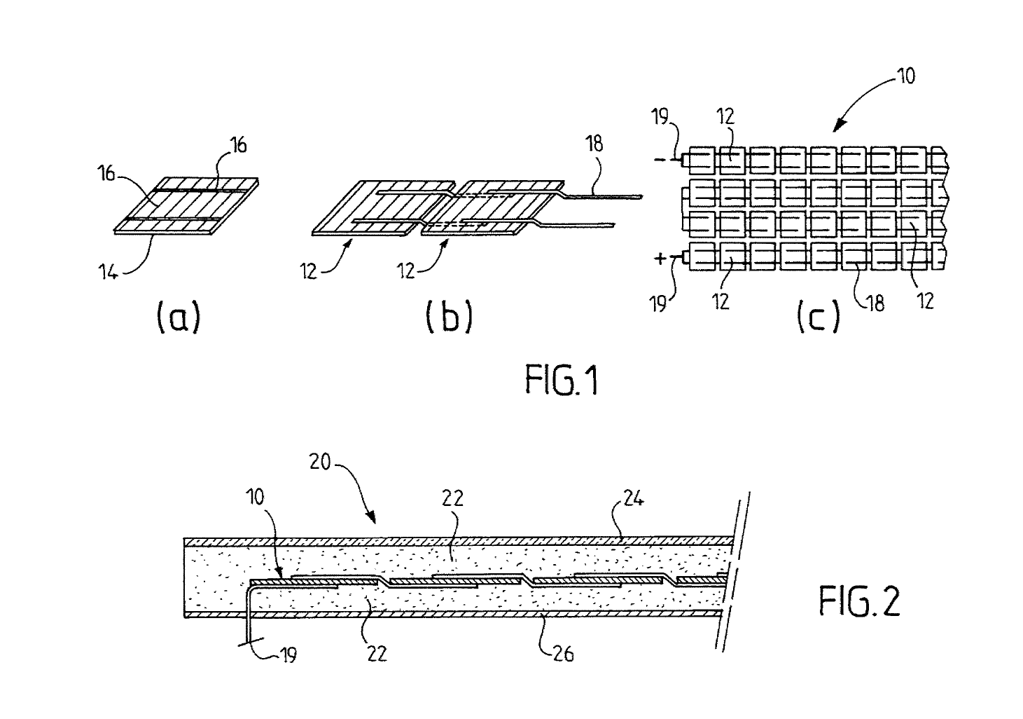

### DETAILED DESCRIPTION OF THE INVENTION

Regarding the polyolefin backbone relating to the skin part, it is a polymer comprising an α-olefin as monomer. Equally, what follows also extends in connection with the core part of the encapsulant when the comonomer of the copolymer is an α-olefin.

α-Olefins having from 2 to 30 carbon atoms are preferred.

As α-olefin, mention may be made of ethylene, propylene, 1-butene, 1-pentene, 3-methyl-1-butene, 1-hexene, 4-methyl-1-pentene, 3-methyl-1-pentene, 1-octene, 1-decene, 1-dodecene, 1-tetradecene, 1-hexadecene, 1-octadecene, 1-eicosene, 1-docosene, 1-tetracosene, 1-hexacosene, 1-octacosene and 1-triacontene.

Mention may also be made of cycloolefins having from 3 to 30 carbon atoms, preferably from 3 to 20 carbon atoms, such as cyclopentane, cycloheptene, norbornene, 5-methyl-2-norbornene, tetracyclododecene and 2-methyl-1,4,5,8-dimethano-1,2,3,4,4a,5,8,8a-octahydronaphthalene; diolefins and polyolefins, such as butadiene, isoprene, 4-methyl-1,3-pentadiene, 1,4-pentadiene, 1,5-hexadiene, 1,3-hexadiene, 1,3-octadiene, 1,4-octadiene, 1,5-octadiene, 1,6-octadiene, ethylidiene norbornene, vinyl norbornene, dicyclopentadiene, 7-methyl-1,6-octadiene, 4-ethylidiene-8-methyl-1,7-nonadiene and 5,9-dimethyl-1,4,8-decatriene; vinylaromatic compounds such as monoalkylstyrenes or polyalkylstyrenes (including styrene, o-methylstyrene, m-methylstyrene, p-methylstyrene, o,p-dimethylstyrene, o-ethylstyrene, m-ethylstyrene and p-ethylstyrene), and derivatives comprising functional groups such as methoxystyrene, ethoxystyrene, vinylbenzoic acid, vinylmethyl benzoate, vinylbenzyl acetate, hydroxystyrene, o-chlorostyrene, p-chlorostyrene, divinylbenzene, 3-phenylpropene, 4-phenylpropene, α-methylstyrene, vinyl chloride, 1,2-difluoroethylene, 1,2-dichioroethylene, tetrafluoroethylene and 3,3,3-trifluoro-1-propene.

Within the context of the present invention, the term “α-olefin” also comprises styrene. Propylene, and very especially ethylene, are preferred as α-olefin.

This polyolefin may be a homopolymer when a single α-olefin is polymerized in the polymer chain. Mention may be made, as examples, of polyethylene (PE) or polypropylene (PP).

This polyolefin may also be a copolymer when at least two comonomers are copolymerized in the polymer chain, one of the two comonomers referred to as the “first comonomer” being an α-olefin and the other comonomer, referred to as the “second comonomer”, is a monomer capable of polymerizing with the first monomer.

As the second comonomer, mention may be made of:
one of the α-olefins already mentioned, the latter being different from the first α-olefin comonomer,
dienes, such as for example 1,4-hexadiene, ethylidene norbornene and butadiene,
unsaturated carboxylic acid esters such as, for example, alkyl acrylates or alkyl methacrylates grouped together under the term alkyl (meth)acrylates. The alkyl chains of these (meth)acrylates may have up to 30 carbon atoms. Mention may be made, as alkyl chains, of methyl, ethyl, propyl, n-butyl, sec-butyl, isobutyl, tert-butyl, pentyl, hexyl, heptyl, octyl, 2-ethylhexyl, nonyl, decyl, undecyl, dodecyl, tridecyl, tetradecyl, pentadecyl, hexadecyl, heptadecyl, octadecyl, nonadecyl, eicosyl, heneicosyl, docosyl, tricosyl, tetracosyl, pentacosyl, hexacosyl, heptacosyl, octacosyl, nonacosyl. Methyl, ethyl and butyl (meth)acrylates are preferred as unsaturated carboxylic acid esters,
carboxylic acid vinyl esters. As examples of carboxylic acid vinyl esters, mention may be made of vinyl acetate, vinyl versatate, vinyl propionate, vinyl butyrate or vinyl maleate. Vinyl acetate is preferred as carboxylic acid vinyl ester.

Advantageously, the polyolefin backbone comprises at least 50 mol % of the first comonomer; its density may advantageously be between 0.91 and 0.96.

The preferred polyolefin backbones consist of an ethylene/alkyl (meth)acrylate copolymer. By using this polyolefin backbone, excellent aging, light and temperature resistance are obtained.

It would not be outside of the scope of the invention if different “second comonomers” were copolymerized in the polyolefin backbone.

According to the present invention, the polyolefin backbone contains at least one residue of an unsaturated monomer (X) that can react at an acid and/or amine function of the polyamide graft via a condensation reaction. According to the definition of the invention, the unsaturated monomer (X) is not a “second comonomer”.

As unsaturated monomer (X) included in the polyolefin backbone, mention may be made of:
unsaturated epoxides. Among these are for example aliphatic glycidyl esters and ethers such as allyl glycidyl ether, vinyl glycidyl ether, glycidyl maleate and glycidyl itaconate, glycidyl acrylate and glycidyl methacrylate. They are also, for example, alicyclic glycidyl esters and ethers such as 2-cyclohexene-1-glycidyl ether, glycidyl cyclohexene-4,5-dicarboxylate, glycidyl cyclohexene-4-carboxylate, glycidyl 5-norbornene-2-methyl-2-carboxylate and diglycidyl endo-cis-bicyclo-[2.2.1]-5-heptene-2,3-dicarboxylate. As unsaturated epoxide, glycidyl methacrylate is preferably used.
unsaturated carboxylic acids and their salts, for example acrylic acid or methacrylic acid and the salts of these same acids.
carboxylic acid anhydrides. They may be chosen, for example, from maleic, itaconic, citraconic, allylsuccinic, cyclohex-4-ene-1,2-dicarboxylic, 4-methylenecyclohex-4-ene-1,2-dicarboxylic, bicyclo-[2.2.1]hept-5-ene-2,3-dicarboxylic and x-methylbicyclo[2.2.1]hept-5-ene-2,2-dicarboxylic anhydrides. As carboxylic acid anhydride, maleic anhydride is preferably used.

The unsaturated monomer (X) is preferably chosen from an unsaturated carboxylic acid anhydride and an unsaturated epoxide. In particular, for achieving the condensation of the polyamide graft with the polyolefin backbone, in the case where the reactive end of the polyamide graft is a carboxylic acid function, the unsaturated monomer (X) is preferably an unsaturated epoxide. In the case where the reactive end of the polyamide graft is an amine function, the unsaturated monomer (X) is advantageously an unsaturated epoxide and preferably an unsaturated carboxylic acid anhydride.

According to one advantageous version of the invention, the preferred number of unsaturated monomers (X) attached, on average, to the polyolefin backbone is greater than or equal to 1.3 and/or preferably less than or equal to 10.

Thus, when (X) is maleic anhydride and the number-average molar mass of the polyolefin is 15 000 g/mol, it was found that this corresponded to an anhydride proportion of at least 0.8%, and at most 6.5%, by weight of the whole of the polyolefin backbone. These values associated with the mass of the polyamide grafts determine the proportion of polyamide and of backbone in the polyamide graft polymer.

The polyolefin backbone containing the residue of the unsaturated monomer (X) is obtained by polymerization of the monomers (first comonomer, optional second comonomer, and optionally unsaturated monomer (X)). This polymerization can be carried out by a high-pressure radical process or a process in solution, in an autoclave or tubular reactor, these processes and reactors being well known to a person skilled in the art. When the unsaturated monomer (X) is not copolymerized in the polyolefin backbone, it is grafted to the polyolefin backbone. The grafting is also an operation that is known per se. The composition would be in accordance with the invention if several different functional monomers (X) were copolymerized with and/or grafted to the polyolefin backbone.

Depending on the types and ratio of monomers, the polyolefin backbone may be semicrystalline or amorphous. In the case of amorphous polyolefins, only the glass transition temperature is observed, whereas in the case of semicrystalline polyolefins a glass transition temperature and a melting temperature (which will inevitably be higher) are observed. A person skilled in the art will only have to select the ratios of monomer and the molecular masses of the polyolefin backbone in order to be able to easily obtain the desired values of the glass transition temperature, optionally of the melting temperature, and also of the viscosity of the polyolefin backbone.

Preferably, the polyolefin has a melt flow index (MFI) between 3 and 400 g/10 min (190° C., 2.16 kg, ASTM D 1238).

The polyamide grafts may be either homopolyamides or copolyamides.

The expression “polyamide grafts” especially targets the aliphatic homopolyamides which result from the polycondensation:
of a lactam;
or of an aliphatic α,ω-aminocarboxylic acid;
or of an aliphatic diamine and an aliphatic diacid.

As examples of a lactam, mention may be made of caprolactam, oenantholactam and lauryllactam.

As examples of an aliphatic α,ω-aminocarboxylic acid, mention may be made of aminocaproic acid, 7-aminoheptanoic acid, 11-aminoundecanoic acid and 12-aminododecanoic acid.

As examples of an aliphatic diamine, mention may be made of hexamethylenediamine, dodecamethylenediamine and trimethylhexamethylenediamine.

As examples of an aliphatic diacid, mention may be made of adipic, azelaic, suberic, sebacic and dodecanedicarboxylic acids.

Among the aliphatic homopolyamides, mention may be made, by way of example and nonlimitingly, of the following polyamides: polycaprolactam (PA-6); polyundecanamide (PA-11, sold by Arkema under the brand Rilsan®); polylauryllactam (PA-12, also sold by Arkema under the brand Rilsan®); polybutylene adipamide (PA-4,6); polyhexamethylene adipamide (PA-6,6); polyhexamethylene azelamide (PA-6,9); polyhexamethylene sebacamide (PA-6,10); polyhexamethylene dodecanamide (PA-6,12); polydecamethylene dodecanamide (PA-10,12); polydecamethylene sebacamide (PA-10,10) and polydodecamethylene dodecanamide (PA-12,12).

The expression “semicrystalline polyamides” also targets cycloaliphatic homopolyamides.

Mention may especially be made of the cycloaliphatic homopolyamides which result from the condensation of a cycloaliphatic diamine and an aliphatic diacid.

As an example of a cycloaliphatic diamine, mention may be made of 4,4′-methylenebis(cyclohexylamine), also known as para-bis(aminocyclohexyl)methane or PACM, 2,2′-dimethyl-4,4′-methylenebis(cyclohexylamine), also known as bis(3-methyl-4-aminocyclohexyl)methane or BMACM.

Thus, among the cycloaliphatic homopolyamides, mention may be made of the polyamides PACM.12 resulting from the condensation of PACM with the C12 diacid, BMACM.10 and BMACM.12 resulting from the condensation of BMACM with, respectively, C10 and C12 aliphatic diacids.

The expression “polyamide grafts” also targets the semi-aromatic homopolyamides that result from the condensation:
of an aliphatic diamine and an aromatic diacid, such as terephthalic acid (T) and isophthalic acid (I). The polyamides obtained are then commonly known as “polyphthalamides” or PPAs; and
of an aromatic diamine, such as xylylenediamine, and more particularly meta-xylylenediamine (MXD) and an aliphatic diacid.

Thus, nonlimitingly, mention may be made of the polyamides 6.T, 6.I, MXD.6 or else MXD.10.

The polyamide grafts used in the composition according to the invention are preferably copolyamides. These result from the polycondensation of at least two of the groups of monomers mentioned above in order to obtain homopolyamides. The term “monomer” in the present description of the copolyamides should be taken in the sense of a “repeat unit”. This is because the case where a repeat unit of the PA is formed from the combination of a diacid with a diamine is particular. It is considered that it is the combination of a diamine and a diacid, that is to say the diamine-diacid pair (in an equimolar amount), which corresponds to the monomer. This is explained by the fact that individually, the diacid or the diamine is only one structural unit, which is not enough on its own to be polymerized in order to give a polyamide.

Thus, the copolyamides cover especially the condensation products of:
at least two lactams;
at least two aliphatic α,ω-aminocarboxylic acids;
at least one lactam and at least one aliphatic α,ω-aminocarboxylic acid;
at least two diamines and at least two diacids;
at least one lactam with at least one diamine and at least one diacid;
at least one aliphatic α,ω-aminocarboxylic acid with at least one diamine and at least one diacid,
   the diamine(s) and the diacid(s) possibly being, independently of one another, aliphatic, cycloaliphatic or aromatic.

Depending on the types and ratio of monomers, the copolyamides may be semicrystalline or amorphous. In the case of amorphous copolyamides, only the glass transition temperature is observed, whereas in the case of semicrystalline copolyamides a glass transition temperature and a melting temperature (which will inevitably be higher) are observed.

Among the amorphous copolyamides that can be used within the context of the invention, mention may be made, for example, of the copolyamides containing semiaromatic monomers.

Among the copolyamides, it is also possible to use semicrystalline copolyamides and particularly those of the PA-6/11, PA-6/12 and PA-6/11/12 type.

The degree of polymerization may vary to a large extent; depending on its value it is a polyamide or a polyamide oligomer.

Advantageously, the polyamide grafts are monofunctional.

So that the polyamide graft has a monoamine end group, it is sufficient to use a chain limiter of formula:

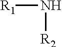

in which:
R1 is hydrogen or a linear, or branched alkyl group containing up to 20 carbon atoms; and
R2 is a group having up to 20 carbon atoms that is a linear or branched alkyl or alkenyl group, a saturated or unsaturated cycloaliphatic radical, an aromatic radical or a combination of the preceding. The limiter may be, for example, laurylamine or oleylamine.

So that the polyamide graft has a carboxylic monoacid end group, it is sufficient to use a chain limiter of formula R′1-COOH, R′1-CO-O-CO-R′2 or a carboxylic diacid.

R′1 and R′2 are linear or branched alkyl groups containing up to 20 carbon atoms.

Advantageously, the polyamide graft has one end group having an amine functionality. The preferred monofunctional polymerization limiters are laurylamine and oleylamine.

Advantageously, the polyamide grafts have a molar mass between 1000 and 5000 g/mol and preferably between 2000 and 3000 g/mol.

The polycondensation defined above is carried out according to commonly known processes, for example at a temperature generally between 200° C. and 300° C., under vacuum or in an inert atmosphere, with stirring of the reaction mixture. The average chain length of the graft is determined by the initial molar ratio between the polycondonsable monomer or the lactam and the monofunctional polymerization limiter. For the calculation of the average chain length, one chain limiter molecule is usually counted per one graft chain.

A person skilled in the art will only have to select the types and ratio of monomers and also choose the molar masses of the polyamide grafts in order to be able to easily obtain the desired values of the glass transition temperature, optionally of the melting temperature and also of the viscosity of the polyamide graft.

The condensation reaction of the polyamide graft on the polyolefin backbone containing the residue of (X) is carried out by reaction of one amine or acid function of the polyamide graft with the residue of (X). Advantageously, monoamine polyamide grafts are used and amide or imide bonds are created by reacting the amine function with the function of the residue of (X).

This condensation is preferably carried out in the melt state. To manufacture the composition according to the invention, it is possible to use conventional kneading and/or extrusion techniques. The components of the composition are thus blended to form a compound which may optionally be granulated on exiting the die. Advantageously, coupling agents are added during the compounding.

To obtain a nanostructured composition, it is thus possible to blend the polyamide graft and the backbone in an extruder, at a temperature generally between 200° C. and 300° C. The average residence time of the molten material in the extruder may be between 5 seconds and 5 minutes, and preferably between 20 seconds and 1 minute. The efficiency of this condensation reaction is evaluated by selective extraction of free polyamide grafts, that is to say those that have not reacted to form the polyamide graft polymer.

The preparation of polyamide grafts having an amine end group and also their addition to a polyolefin backbone containing the residue of (X) is described in U.S. Pat No. 3,976,720, U.S. Pat. No. 3,963,799, U.S. Pat. No. 5,342,886 and FR 2291225.

The polyamide graft polymer of the present invention advantageously has a nanostructured organization. To obtain this type of organization, use will preferably be made, for example, of grafts having a number-average molar mass Mₙ between 1000 and 5000 g/mol and more preferably between 2000 and 3000 g/mol. Use will also preferably be made of 15% to 30% by weight of polyamide grafts and a number of monomers (X) between 1.3 and 10.

The flow temperature of the polyamide graft polymer is defined as the highest temperature among the melting temperatures and the glass transition temperatures of the polyamide grafts and of the polyolefin backbone. The backbone and the grafts are chosen so that the flow temperature of the polyamide graft polymer is greater than or equal to 75° C. and less than or equal to 160° C., which allows a processing temperature that is particularly well suited to the current techniques for manufacturing solar panels.

Regarding the core layer, the latter consists of at least one polyolefin containing a polyethylene chosen from a homopolymer of ethylene or a copolymer comprising at least 50 mol % of ethylene and of one or more comonomers. The core layer consists of a blend of polyolefins or of several different polyolefin layers positioned adjacent to one another.

The following relate to the definition of one or more comonomers. Thus, regarding the comonomer, mention may be made of:
as previously mentioned, α-olefins, advantageously those having from 3 to 30 carbon atoms. These α-olefins may be used alone or as a mixture of two or more than two. As an α-olefin, mention may be made of ethylene, propylene, 1-butene, 1-pentene, 3-methyl-1-butene, 1-hexene, 4-methyl-1-pentene, 3-methyl-1-pentene, 1-octene, 1-decene, 1-dodecene, 1-tetradecene, 1-hexadecene, 1-octadecene, 1-eicosene, 1-docosene, 1-tetracosene, 1-hexacosene, 1-octacosene and 1-triacontene. Preferably, the polyethylenes comprise one or more α-olefins comprising 3 to 8 carbons, with an ethylene content of greater than 50%. Ethylene/α-olefin copolymers are conventionally obtained by processes known to a person skilled in the art, such as for example by Ziegler-Natta, metallocene or organometallic polymerization as described in document WO 2008/036707. The density of these polymers measured according to the ASTM D 1505 standard may be from 0.860 to 0.96, advantageously from 0.860 to 0.920. Very preferably, the polyethylene (A) or (A1) is a linear low-density polyethylene (LLDPE).
unsaturated carboxylic acid esters such as, for example, alkyl acrylates or alkyl methacrylates grouped together under the term alkyl (meth)acrylates. The alkyl chains of these (meth)acrylates may have up to 30 carbon atoms. Mention may be made, as alkyl chains, of methyl, ethyl, propyl, n-butyl, sec-butyl, isobutyl, tert-butyl, pentyl, hexyl, heptyl, octyl, 2-ethylhexyl, nonyl, decyl, undecyl, dodecyl, tridecyl, tetradecyl, pentadecyl, hexadecyl, heptadecyl, octadecyl, nonadecyl, eicosyl, heneicosyl, docosyl, tricosyl, tetracosyl, pentacosyl, hexacosyl, heptacosyl, octacosyl, nonacosyl. Methyl, ethyl and butyl (meth)acrylates are preferred as unsaturated carboxylic acid esters. Unsaturated carboxylic acid esters such as, for example, alkyl (meth)acrylates, it being possible for the alkyls to have up to 24 carbon atoms, examples of an alkyl acrylate or methacrylate are in particular methyl methacrylate, ethyl acrylate, n-butyl acrylate, isobutyl acrylate, 2-ethylhexyl acrylate. Ethylene/carboxylic acid ester copolymers are conventionally obtained by processes known to a person skilled in the art, such as for example the high-pressure autoclave or tubular process;
carboxylic acid vinyl esters. As examples of carboxylic acid vinyl esters, mention may be made of vinyl acetate, vinyl versatate, vinyl propionate, vinyl butyrate or vinyl maleate. Vinyl acetate is preferred as carboxylic acid vinyl ester;
dienes, such as for example 1,4-hexadiene.

The polyolefin may also comprise an additional functional monomer chosen from unsaturated carboxylic acid anhydrides, unsaturated dicarboxylic acid anhydrides, unsaturated carboxylic acids and unsaturated epoxides. As unsaturated monomers included in the polyolefin backbone, there are:
Unsaturated epoxides are for example aliphatic glycidyl esters and ethers such as allyl glycidyl ether, vinyl glycidyl ether, glycidyl maleate and glycidyl itaconate, glycidyl acrylate and glycidyl methacrylate. They are also, for example, alicyclic glycidyl esters and ethers such as 2-cyclohexene-1-glycidyl ether, glycidyl cyclohexene-4,5-dicarboxylate, glycidyl cyclohexene-4-carboxylate, glycidyl 5-norbornene-2-methyl-2-carboxylate and diglycidyl endo-cis-bicyclo[2.2.1]-5-heptene-2,3-dicarboxylate. As unsaturated epoxide, glycidyl methacrylate is preferably used.
Unsaturated carboxylic acids and their salts, for example acrylic acid or methacrylic acid and the salts of these same acids.
Carboxylic acid anhydrides or dicarboxylic acid anhydrides may be chosen, for example, from maleic, itaconic, citraconic, allylsuccinic, cyclohex-4-ene-1,2-dicarboxylic, 4-methylenecyclohex-4-ene-1,2-dicarboxylic, bicyclo[2.2.1]hept-5-ene-2,3-dicarboxylic and x-methyl-bicyclo[2.2.1]hept-5-ene-2,2-dicarboxylic anhydrides. As anhydride, maleic anhydride is preferably used.

In the latter case, these copolymers comprising these functional monomers are obtained by polymerization of the monomers (first comonomer, optional second comonomer, and optionally functional monomer). This polymerization can be carried out by a high-pressure radical process or a process in solution, in an autoclave or tubular reactor, these processes and reactors being well known to a person skilled in the art. When the functional monomer is not copolymerized in the polyolefin backbone, it is grafted to the polyolefin backbone. The grafting is also an operation that is known per se. The composition would be in accordance with the invention if several different functional monomers were copolymerized with and/or grafted to the polyolefin backbone.

Preferably, the polyolefin has a melt flow index (MFI) between 3 and 400 g/10 min (190° C.; 2.16 kg; ASTM D 1238).

Fillers, in particular mineral fillers, may be added in order to improve the thermomechanical resistance of the composition. Given nonlimitingly as examples are silica, alumina or calcium carbonates or carbon nanotubes. Advantageously, use is made of modified or unmodified clays, which are mixed on the nanometer scale; this makes it possible to obtain a more transparent composition.

Plasticizers could be added in order to facilitate processing and improve the productivity of the process for manufacturing the composition and the structures. Mention will be made, as examples, of paraffinic, aromatic or naphthalenic mineral oils which also make it possible to improve the adhesive strength of the composition according to the invention. Mention may also be made, as plasticizers, of phthalates, azelates, adipates, and tricresyl phosphate.

Flame retardants could also be added. It is also possible to add coloring or whitening compounds.

Regarding the aspects of the invention relating to the use of the thermoplastic composition in a photovoltaic module, a person skilled in the art may refer, for example, to the Handbook of Photovoltaic Science and Engineering, Wiley, 2003. Indeed, the composition of the invention may be used as an encapsulant or encapsulant-backsheet in a photovoltaic module, the structure of which is described in relation to the appended figures.

Among the list of additives below, a person skilled in the art will easily know how to select their amounts in order to obtain the desired properties of the composition, in particular in its application in photovoltaic modules.

Coupling agents, although not necessary, may advantageously be added in order to improve the adhesive strength of the composition when this adhesive strength must be particularly high. The coupling agent is a non-polymeric ingredient; it may be organic, crystalline, mineral and more preferably semi-mineral semi-organic. Among the latter, mention may be made of organic titanates or silanes, such as for example monoalkyl titanates, trichlorosilanes and trialkoxysilanes.

Although crosslinking is not obligatory, it is possible for further improving the thermomechanical properties of the encapsulant, in particular when the temperature becomes very high. It is not therefore outside the scope of the invention if crosslinking agents are added. Mention may be made, by way of example, of isocyanates or organic peroxides. This crosslinking may also be carried out by known irradiation techniques.

Preferably, the composition comprises no more than 10% tackifying resin and preferably does not contain any. Indeed, when these resins are added to the polyamide graft polymer, the transparency of the composition and the creep resistance decrease. These tackifying resins are, for example, rosins and derivatives thereof, polyterpenes and derivatives thereof. Surprisingly, no tackifying resin is necessary for giving the composition properties of adhesion to the various supports of solar modules.

In this particular application of the composition in photovoltaic modules, since the UV radiation is capable of resulting in a slight yellowing of the composition used as an encapsulant for said modules, UV stabilizers may be added in order to ensure the transparency of the encapsulant during its service life. These compounds may be, for example, based on benzophenone or benzotriazole. They can be added in amounts of less than 10%, and preferably of from 0.1% to 5%, by weight of the total weight of the composition.

### Obtaining the Formulations Tested:

Single-layer and three-layer films of 400 μm were produced by cast film extrusion on a Dr COLLIN brand extrusion line. This extrusion line is composed of three extruders equipped with a standard polyolefin screw profile, a variable coextrusion block (variable feedblock), and a 250 mm coat hanger die. The coextrusion block allows the production of a film having three layers (layer 1/layer 2/layer 3) with a variable distribution of thicknesses (e.g.: 50/300/50 microns). In the particular and nonlimiting case of the examples presented in the patents, the process parameters were set:
extrusion temp for layers 1 and 3: 150° C.;
extrusion temp for layer 2: 200-220° C. depending on the polymers to be extruded;
coextrusion box and die temp: 180° C.;
line speed is 2.6 m/min.

### Materials Used for Forming the Formulations Tested:

Apolhya Solar® LC3UV:

The Apolhya Solar® family is a family of polymers sold by ARKEMA which combine the properties of polyamides with those of polyolefins owing to co-continuous morphologies being obtained on the nanometer scale. Within the context of the tests, Apolhya Solar® LC3UV is used here, which is one of the grades of the Apolhya Solar® family which is characterized by an MFI (Melt Flow Index) of 10 grams/10 minutes at 230° C. under 2.16 kg sold by the applicant. This product has an elastic modulus of 65 MPa at ambient temperature and a melting point of 130° C.

Infuse™ 9817.15 and Infuse™ 9807.15:

The Infuse™ range is a range of polyolefin block copolymers sold by DOW combining hard crystalline blocks with soft amorphous blocks. The Infuse™ 9817.15 grade is characterized by a density of 0.87, a melting temperature of 120° C. and an MFI of 15 g/10 min (190° C., 2.16 kg). The Infuse™ 9807.15 grade is characterized by a density of 0.866, a melting temperature of 118° C. and an MFI of 15 g/10 min (190° C., 2.16 kg).

Lotryl® 20MA08:

The Lotryl range is a range of ethylene/alkyl acrylate statistical copolymers sold by ARKEMA. Lotryl® 20MA08 is an ethylene/methyl acrylate statistical copolymer containing 20% by weight of methyl acrylate. It is characterized by an MFI of 8 g/10 min (190° C., 2.16 kg) and a melting temperature of 85° C.

PE LA 0710:

PE LA 0710 is a low-density polyethylene from TOTAL PETROCHEMICALS. It is characterized by an MFI of 7.5 g/10 min (190° C., 2.16 kg) and a melting temperature of 108° C.

### Description of the Films Produced

Three-layer and single-layer films were produced by cast film extrusion. The three-layer films consist of two outer layers of Apolhya Solar® of 50 μm (micrometers) each and the central layer of 300 μm consists of a polyolefin described in the following paragraph. Single-layer 400 μm films of Apolhya Solar® LC3-UV, of each of the polyolefins used in the three-layer films and of Apolhya Solar® LC3-UV/polyolefin alloys (25 wt %/75 wt %) were also produced.

The present invention is illustrated in greater detail by the following nonlimiting examples.

### EXAMPLE 1

The film is a 400 μm three-layer film consisting of two outer layers of Apolhya Solar® LC3-UV of 50 μm each and of a 300 μm central layer of Infuse™ 9817.15.

### EXAMPLE 2

The film is a 400 μm three-layer film consisting of two outer layers of Apolhya Solar® LC3-UV of 50 μm each and of a 300 μm central layer of Infuse™ 9807.15.

### EXAMPLE 3

The film is a 400 μm three-layer film consisting of two outer layers of Apolhya Solar® LC3-UV of 50 μm each and of a 300 μm central layer of Lotryl™ 20MA08.

### EXAMPLE 4

The film is a 400 μm three-layer film consisting of two outer layers of Apolhya Solar® LC3-UV of 50 μm each and of a 300 μm central layer of PE LA 0710.

### COMPARATIVE EXAMPLE 1

The film is a 400 μm single-layer film consisting of Apolhya Solar® LC3-UV.

### COMPARATIVE EXAMPLE 2

The film is a 400 μm single-layer film consisting of Infuse™ 9817.15.

### COMPARATIVE EXAMPLE 3

The film is a 400 μm single-layer film consisting of Infuse™ 9807.15.

### COMPARATIVE EXAMPLE 4

The film is a 400 μm single-layer film consisting of Lotryl® 20MA08.

### COMPARATIVE EXAMPLE 5

The film is a 400 μm single-layer film consisting of PE LA 0710.

### COMPARATIVE EXAMPLE 6

The film is a 400 μm single-layer film consisting of a mixture of Infuse™ 9817.15 and of Apolhya Solar® LC3-UV containing 75% by weight of Infuse™ 9817.15. This film has the same overall composition as the film from Example 1. The composition is obtained by dry mixing of granules before the extrusion of the film.

### COMPARATIVE EXAMPLE 7

The film is a 400 μm single-layer film consisting of a mixture of PE LA 0710 and of Apolhya Solar® LC3-UV containing 75% by weight of PE LA 0710. The composition is obtained by dry mixing of granules before the extrusion of the film.

### Tests Carried Out on the Test Specimens:

Creep Resistance Test:

The creep test carried out here consists in applying a tensile stress at high temperature for a given time then measuring the residual deformation at ambient temperature after having removed the stress. This creep test is carried out on test specimens of IFC (French Institute of Rubber) type cut from the films. The stress is 0.5 MPa. It is applied for 15 minutes at a temperature between 100° C. and 120° C.

Optical Properties:

The optical properties of the films were determined by measuring the transmittance in the visible range, and the haze. The transmittance of the films was evaluated between 400 nm and 740 nm according to the ASTM D1003 standard with an illuminant C under 2° with the aid of a CM-3610d spectrocolorimeter from Minolta. In order to determine a transmittance value that is free of surface effects, each film was pressed between 2 glass plates using a laboratory-scale laminator from Penergy. In order to come up with the transmittance of the encapsulant, a transmittance measurement is carried out on the glass/encapsulant film/glass structure and on a glass plate. The measurement on the glass plate alone makes it possible to deduct the contribution of the glass to the transmittance from the glass/encapsulant/glass structure. The total transmittance of the encapsulant film is finally determined by adding up the transmittances for each wavelength between 400 nm and 740 nm. For a thermoplastic composition, a transmittance of greater than or equal to 90% is considered to be satisfactory.

The haze is measured on glass/encapsulant film/glass structures according to ASTM D 1003 with an illuminant C under 2°. For a thermoplastic composition, a haze of less than or equal to 25% is considered to be satisfactory.

Water Vapor Permeability:

The water vapor permeability of the films is estimated according to the ASTM E96 standard, method A, at 23° C. and 85% relative humidity and 85° C. and 85% relative humidity.

Adhesion to Glass:

The adhesion to glass was evaluated according to the following protocol. A glass/encapsulant film/backsheet structure is laminated for 15 minutes at 150° C. using the laminator from Penergy. The thickness of the encapsulant film is 400 μm. The backsheet is made of KPE (Kynar/PET/EVA). The adhesion at the glass/encapsulant interface is evaluated using a 90° peel test carried out at 100 mm/min on a Zwyck 1445 tensile testing machine. The width of the peel arms is 15 mm. The peel strength is expressed in N/15 mm.

The composition must satisfy all of the aforementioned tests in an optimal manner in order to be considered to be satisfactory from the point of view of its adhesive properties, its thermomechanical properties or in other words the preservation of its mechanical properties at high temperature (hot creep), its water vapor barrier properties and finally with regard to its transparency. It is clearly understood that the difficulty consists in finding a composition that exhibits good performances for all of the properties tested and that a single one of these properties at a low level is enough to disqualify this composition.

As can be observed, the applicant observed, after its experiments, that, surprisingly, the composition according to the invention perfectly satisfied all of the tests demonstrating that its properties of transparency and of adhesion to various supports and its mechanical, thermomechanical, flame retardant and electrical insulation properties are excellent, or in other words of a very high level.

The compositions according to the invention therefore fulfill the criteria for being able to be very advantageously used as a binder or encapsulant in solar modules.

It will be noted that the composition according to the invention is defined at the least by the combination of a skin layer with a core layer as defined previously. Indeed, despite the fact that the tests for the compositions according to the invention were carried out on the basis of a skin-core-skin three-layer combination, it is possible for a person skilled in the art to extrapolate these results to the combination of two skin-core layers.

In the same manner, the composition examples according to the invention all have the same thicknesses regarding the skin layer and core layer but it is clearly understood that a person skilled in the art could vary them as a function of the application of the photovoltaic module and of the performances of the latter with regard to the intrinsic properties of the skin layer and of the core layer, notwithstanding the synergy produced between these two layers that form the encapsulant.

### Results of the Tests Carried Out on the Test Specimens of Various Formulations:

| | | | | Creep | | | | | |
|---|---|---|---|---|---|---|---|---|---|
| | | | | Elongation | | | Water vapor | | |
| | Outer | Inner | Outer | at 110° C. | Optical properties | | permeability | | |
| | layer | layer | layer | (under 0.5 bar, | Transmittance (%) | Haze | (g. 25 μm/m²/24 h) | | Adhesion |
| | (50 μm) | (300 μm) | (50 μm) | 15 min) | (400 nm-740 nm) | (%) | 23° C./85% RH | 85° C./85% RH | N/15 mm |
| Example 1 | LC3-UV | Infuse 9817.15 | LC3-UV | 15% | 92 | 38 | 33 | ~2250 | >60 |
| Example 2 | LC3-UV | Infuse 9807.15 | LC3-UV | 17.50% | 93 | 32 | 33 | ~2250 | >60 |
| Example 3 | LC3-UV | Lotryl 20MA08 | LC3-UV | breaks at | 96.5 | 4 | ~50 | — | >60 |
| | | | | 1 min | | | | | |
| Example 4 | LC3-UV | LA 710 | LC3-UV | 200% | 91 | 36 | 9 | 1250 | >60 |

| | | | | | | | |
|---|---|---|---|---|---|---|---|
| Comparative | LC3-UV | 35% | 96.5 | 2 | 87 | 5413 | >60 |
| Example 1 | | | | | | | |
| Comparative | Infuse 9817.15 | 17.50% | 89 | 66 | 28 | 1883 | 0 |
| Example 2 | | | | | | | |
| Comparative | Infuse 9807.15 | 17.50% | 89 | 66 | 28 | 1883 | 0 |
| Example 3 | | | | | | | |
| Comparative | Lotryl 20MA08 | Creeps in | 97 | 1 | 70 | not | 0 |
| Example 4 | | less than | | | | measurable | |
| | | 1 min | | | | | |
| Comparative | PE LA 710 | 300% | 88 | 60 | 7 | 1000 | 0 |
| Example 5 | | | | | | | |
| Comparative | LC3-UV + Infuse 9817.15 (25/75) | 17.50% | 85 | 65 | 40 | 2530 | <20 |
| Example 6 | blend | | | | | | |
| Comparative | LC3-UV + PE LA 710 (25/75) | 15% | 85 | 70 | 20 | 1800 | <20 |
| Example 7 | blend | | | | | | |

1. A photovoltaic module encapsulant, adapted to encase a photovoltaic cell, comprising at least two adjacent thermoplastic layers forming a core-skin assembly, wherein:
the skin layer consists of a polyamide graft polymer comprising a polyolefin backbone, representing from 50% to 95% by weight of the polyamide graft polymer, containing a residue of at least one unsaturated monomer (X) and at least one polyamide graft, representing from 5% to 50% by weight of said polyamide graft polymer, wherein:
the polyamide graft is attached to the polyolefin backbone by the residue of the unsaturated monomer (X) comprising a function capable of reacting via a condensation reaction with a polyamide having at least one amine end and/or at least one carboxylic acid end,
the residue of the unsaturated monomer (X) is attached to the backbone by grafting or copolymerization, and
the polyolefin backbone and the polyamide graft being chosen so that said polyamide graft polymer has a flow temperature of greater than or equal to 75° C. and less than or equal to 160° C., this flow temperature being defined as the highest temperature among the melting temperatures and glass transition temperatures of the polyamide graft and of the polyolefin backbone; and
the core layer consists of at least one polyolefin containing a polyethylene chosen from a homopolymer of ethylene or a copolymer chosen from an ethylene/α-olefin copolymer, the density of which is between 0.865 and 0.900 (ASTM D 1505 standard), and an ethylene/alkyl(meth)acrylate/anhydride copolymer.

2. The encapsulant as claimed in claim 1, wherein the skin layer is nanostructured.

3. The encapsulant as claimed in claim 1, wherein the number-average molar mass of polyamide graft is within the range extending from 1000 to 5000 g/mol.

4. The encapsulant as claimed in claim 1, wherein the at least one polyamide graft comprises at least one copolyamide.

5. The encapsulant as claimed in claim 1, wherein the polyolefin backbone does not have a melting temperature or has a melting temperature below 110° C.

6. The encapsulant as claimed in claim 1, wherein the number of monomers (X) attached to the polyolefin backbone is greater than or equal to 1.3 and less than or equal to 10.

7. The encapsulant as claimed in claim 1, wherein the thickness of said encapsulant is between 10 μm and 2000 μm, the thickness of a skin layer varying from 1 μm to 1980 μm and the core layer having a thickness at least equal to 5 μm.

8. The encapsulant as claimed in claim 7, wherein the thickness of said encapsulant is between 200 μm and 600 μm.

9. The encapsulant as claimed in claim 1, wherein the encapsulant consists of two adjacent layers that form a core-skin assembly or of three adjacent layers forming a skin-core-skin assembly where the two skin layers surround the core layer.

10. The encapsulant as claimed in claim 1, wherein the core layer consists of a blend of polyolefins or of several different polyolefin layers positioned adjacent to one another.

11. The encapsulant as claimed in claim 1, wherein the homopolymer of ethylene is a linear low-density polyethylene (LLDPE).

12. A photovoltaic module comprising a structure consisting of a combination of at least one encapsulant and a frontsheet or backsheet, wherein the encapsulant is as claimed in claim 1.

13. The encapsulant as claimed in claim 1, wherein the number-average molar mass of polyamide graft is within the range extending from 2000 to 3000 g/mol.

14. The encapsulant as claimed in claim 9, wherein the two skin layers that surround the core layer are identical.

15. The encapsulant as claimed in claim 1, wherein the homopolymer of ethylene is a linear low-density polyethylene (LLDPE) obtained by metallocene catalysis.
